(19) United States
(12) Patent Application Publication
(10) Pub. No.: US 2026/0004516 A1
(43) Pub. Date: Jan. 1, 2026

(54) REAL TIME IMAGE CONVERTER USING 2D TO 3D RENDERING FOR PHYSICAL STRUCTURE INSPECTION AND MAINTENANCE

(71) Applicant: DELL PRODUCTS L.P., Round Rock, TX (US)

(72) Inventors: Qing Ye, Hopkinton, MA (US); Zhisong Liu, Lahti (FI); Rowland Shaw, Chester, NH (US)

(21) Appl. No.: 18/759,445

(22) Filed: Jun. 28, 2024

(51) Int. Cl. G06T 17/00; G06F 30/13; G06T 15/00

(52) U.S. Cl. CPC G06T 17/00; G06T 15/005; G06F 30/13

(57) ABSTRACT

A structure inspection system includes an image conversion device located in a far edge of the structure inspection system that is proximate to a physical structure, and a near edge processor located in a near edge of the structure inspection system that is remote from the physical structure. The image conversion device receives an image of the physical structure, and renders a real time 3D model of the physical structure based on the first images. The near edge processor is configured to provide a baseline 3D model of the physical structure to the image conversion device. The image conversion device further compares the first real time 3D model with the baseline 3D model, and provides an indication when the first real time 3D model deviates from the baseline 3D model.

### CROSS REFERENCE TO RELATED APPLICATION

Related subject matter is contained in co-pending U.S. patent application Ser. No. ______ (DC-138593) entitled “REAL TIME IMAGE CONVERTER USING 2D TO 3D RENDERING TO PROVIDE A CONSTRUCTION COMPLIANCE SYSTEM,” filed of even date herewith, the disclosure of which is hereby incorporated by reference.

### FIELD OF THE DISCLOSURE

Embodiments of the present invention generally relate to image generations. More particularly, at least some embodiments of the invention relate to systems, hardware, software, computer-readable media, and methods, for real time rendering of two dimensional images into a three-dimensional image for physical structure inspection and maintenance.

### BACKGROUND

Various approaches have been devised for digital image conversion. For example, Matterport transforms a photographs of a space into BIM (building information modeling) or CAD (computer aided drafting) files to reconstruct a digital three-dimensional (3D) space for viewing or other purposes. Thus, the reconstructed 3D model may be an approximation, such as at BIM LoD (Level of Development) 200-300, of the space that was photographed. However, such a model only indicates the structural configuration of the space from a design point of view, rather than reflecting real world condition such as cracked surfaces, deformations, deteriorating portions, and other conditions. It is noted here that LOD is an industry standard that defines various levels of refinement at which the 3D geometry of the building model can be rendered, and is used as a measure of the service level required.

Approaches such as those just described may be relatively time-consuming. For example, file conversion and BIM reconstruction services typically take about 24 hours, to as long as a few days, depending on considerations such as the size of the space that was photographed.

### BRIEF DESCRIPTION OF THE DRAWINGS

In order to describe the manner in which at least some of the advantages and features of the invention may be obtained, a more particular description of embodiments of the invention will be rendered by reference to specific embodiments thereof which are illustrated in the appended drawings. Understanding that these drawings depict only typical embodiments of the invention and are not therefore to be considered to be limiting of its scope, embodiments of the invention will be described and explained with additional specificity and detail through the use of the accompanying drawings.

FIG. 1 discloses aspects of an example architecture, according to an embodiment.

FIG. 2 discloses aspects of example method, including data flow processes, performed in an architecture, according to one embodiment.

FIG. 3 discloses a table comparing the performance of various 2D-to-3D rendering models.

FIG. 4 discloses some example results from the use of Instant-NGP for 3D modeling.

FIG. 5A shows a crack in a steel beam.

FIG. 5B discloses an example of how various 2D images may be captured of the structures in FIG. 5A.

FIG. 6 shows one possible use case for an embodiment.

FIG. 7A shows a building prior to collapse.

FIG. 7B shows the building of FIG. 7A after collapse.

FIG. 8 discloses aspects of an example computing device configured and operable to perform any of the disclosed methods, processes, and operations.

FIG. 9 illustrates a structure inspection system according to an embodiment.

### DETAILED DESCRIPTION OF SOME EXAMPLE EMBODIMENTS

Embodiments of the present invention generally relate to image generations. More particularly, at least some embodiments of the invention relate to systems, hardware, software, computer-readable media, and methods, for real time rendering of two dimensional images into a three-dimensional image.

One embodiment of the invention comprises a method that uses a real time image converter, which may be located in a far edge environment, that may collaborate with a data orchestration system at a near edge, or core, environment, to enhance the accuracy, speed and cost-savings for multiple use cases, such as remote inspection and immersive experience sharing, for example.

At a device level, a portable image converter, which may be implemented in an edge computing device, may be deployed in an edge environment and may comprise a still camera and/or video camera for image capture, and/or user may access images and/or videos sourced from drones, AR (Augmented reality) goggles, a smartphone, or surrounding surveillance structures, for example. The scope of the invention is not limited to any particular form factor(s) for a portable image converter however, and the foregoing are provided only by way of example.

In an embodiment, a portable image converter may serve as a local compute engine for real time 2D to 3D rendering, and may further comprise a local storage for historical data, and one or more existing 3D models, in order to be able to deliver accurate and fast conclusions based on the outcome of a 2D-3D rendering process. Based on the comparison of a rendered 3D image with prior conditions, a green, yellow, or red, status may be indicated in a short period of time, possibly less than 10 seconds for example. The status indicator may serve as a guide to what further action(s), if any, are required based on the 3D image that has been rendered of the site.

At a system level, one or more 2D images of an initial, or other, condition of, for example, subjects such as a man-made structure such as a building, or a natural feature, such as a mountain, may be used to render a 3D model of the building or natural feature, possibly, but not necessarily, in real time, as a baseline dataset, that is, a 3D model. Additional 2D images may be collected over time to generate one or more additional 3D models that may then be compared with the baseline 3D model and/or with each other to detect conditions, changed conditions, and trends, in the subject for which the 2D images were captures. The condition and trend information may be used to inform progressive analytics and predictive maintenance based on changes observed over time. The repository of 3D models may significantly reduce the demand for computing power for onsite rendering as high resolution rendering may only be needed for the delta areas, that is, areas of particular interest, such as where changes are noted, and/or expected, to be occurring. This tiered computing approach may help to conserve energy and/or conserve the limited computing resources at the portable image converter. Embodiments may be employed in various enterprise, and consumer, use cases, and the use cases disclosed herein are solely for the purposes of illustration, and are not intended to limit the scope of the invention in any way.

Embodiments of the invention, such as the examples disclosed herein, may be beneficial in a variety of respects. For example, and as will be apparent from the present disclosure, one or more embodiments of the invention may provide one or more advantageous and unexpected effects, in any combination, some examples of which are set forth below. It should be noted that such effects are neither intended, nor should be construed, to limit the scope of the claimed invention in any way. It should further be noted that nothing herein should be construed as constituting an essential or indispensable element of any invention or embodiment. Rather, various aspects of the disclosed embodiments may be combined in a variety of ways so as to define yet further embodiments. For example, any element(s) of any embodiment may be combined with any element(s) of any other embodiment, to define still further embodiments. Such further embodiments are considered as being within the scope of this disclosure. As well, none of the embodiments embraced within the scope of this disclosure should be construed as resolving, or being limited to the resolution of, any particular problem(s). Nor should any such embodiments be construed to implement, or be limited to implementation of, any particular technical effect(s) or solution(s). Finally, it is not required that any embodiment implement any of the advantageous and unexpected effects disclosed herein.

In particular, one advantageous aspect of an embodiment of the invention is that 3D images of features of interest may be generated in real time as the 2D images used to generate the 3D image are captured. An embodiment may generate 3D images in environments with limited computing resources. An embodiment may provide structural and other information concerning physical environments that are difficult, or impossible, for a human to access. An embodiment may enable a content creator to share an immersive 3D experience using 2D images. Various other advantages of one or more embodiments of the invention will be apparent from this disclosure.

It is noted that embodiments of the invention, whether claimed or not, cannot be performed, practically or otherwise, in the mind of a human. Accordingly, nothing herein should be construed as teaching or suggesting that any aspect of any embodiment of the invention could or would be performed, practically or otherwise, in the mind of a human. Further, and unless explicitly indicated otherwise herein, the disclosed methods, processes, and operations, are contemplated as being implemented by computing systems that may comprise hardware and/or software. That is, such methods processes, and operations, are defined as being computer-implemented.

### A. Overview

In general, one or more embodiments of the invention may comprise one or more small form factor image conversion devices (SFFICDs), possibly operating in a far edge computing environment, that perform real time 2D to 3D rendering, and 3D model comparison, to support conclusions as to whether, and what, action(s) may need to be taken concerning the subject(s) from which the 3D model(s) were generated. These operations may be performed onsite where the subject is located. Such small form factor image conversion devices, which may be implemented as edge computing devices, may comprise autonomous vehicles such as drones and UAVs (unmanned autonomous vehicle), robots, semi-autonomous, or non-autonomous, vehicles controllable in whole or in part by way of human commands transmitted by way of a user interface (UI), portable computing devices such as tablets, smartphones, and laptops, and any other systems and devices, which may comprise hardware and/or software, that are configured to capture 2D images, which may comprise still and/or video, and to convert one or more of the 2D images, which may be digital and/or analog, to a portion of, or an entire, 3D digital model.

More generally, the scope of the invention is not limited to any particular image conversion device. Note further that an image conversion device may, or may not, also comprise an image capturing device such as a camera for example. In an embodiment, an image conversion device may omit an image capturing device, but may be configured to obtain images from image capturing devices that are located elsewhere, that is, other than at the image conversion device.

In one particular, and non-limiting example, an image conversion device may comprise a variety of components including, but not limited to: one or more cameras, and/or images captured by a drone, smart phone, infrared camera, or other image capturing devices; a 2D-to-3D rendering module; data storage; a comparison module, which may be optional, for example, in a consumer use case; a dataflow and output controller; a wireless communication connection and associated hardware and software, such as, for example, a WiFi connection, cellular connection, or satellite connection; a small graphical display; a speaker; a microphone; and, a file compressor.

An embodiment may further comprise a central system at near edge location/environment, or core location/environment, to host 2D images gathered by image conversion devices and/or other entities. The central system may also store 3D models, and original design files for regulatory compliance. In an embodiment, the central system may perform various functions, such as, but not limited to, to training AI/ML (artificial intelligence/machine learning) algorithms to predict changes with time, integrating with environmental sensor data to root cause the failure, issuing policy or protocols for emergency response, scheduling tasks for each target, and dispatching associated or required prior models, such as may be used as references, by one or more far edge devices, ahead of the tasks in order to reduce rendering time and energy, and fully enable, and employ, the real time compute and processing power of onsite devices, that is, the edge devices.

### B. General Aspects of Some Example Embodiments

One or more embodiments may possess various useful features and advantages, examples of which are discussed hereafter. For example, a portable image converter according to an embodiment may provide accuracy, convenience, efficiency, and sustainability to daily jobs of many auditors and inspection engineers, by implementing 2D to 3D real time rendering at far edge. This approach may eliminate unnecessary physical travel of people to sites of interest, and may reduce or eliminate the need for movement of large amounts of data from the site to the core for processing. The scheduled rendering of 3D at an edge device may require relatively less compute power, as one or more 3D reference models may be pushed out to, or pulled by, the edge device, thus eliminating the need for the edge device to generate the reference models itself. For environments with large scale, real time, rendering needs, the use of 3D reference models may save significant computing resources, reduce rendering at the far edge, reduce required communication bandwidth between the edge and the core, and provide 3D models to the core relatively more quickly.

As another example, a portable image converter may provide millions of content creators the capability of sharing real time immersive experiences by linking physical and virtual worlds. The immersive experience may be shared with users.

In an embodiment, the automatic comparison of the real time rendered 3D model with the design files or prior reference models, which may be spatial or thermal for example, may provide quick insights as to aspects of a component or an area of the target that is out of specification. This information may be useful for designers, engineers, and maintenance personnel, regulation auditors, or quality assurance inspectors, for example.

In an embodiment, the ongoing accumulation of real world 3D models may be used to continuously update a model repository. The models in the model repository may be used for various purposes such as, for example, to monitor the health of the target, measure material behavior, predict trends assisted by AI/DL, detect anomalies, identify root cause(s) of an observed deformation or other anomaly, such as may be due to improper installation, defective materials, and/or unexpected environmental factors, and to alert stakeholders for early intervention to prevent catastrophic failures and/or for the taking of other actions.

Further, in an embodiment, the collaboration of one or more portable image converters with a central scheduling system may enable the automatic dispatch of the relevant prior, or reference, model(s) to the tasked devices to speed up rendering and comparison of 3D models by the device, and may thus eliminate any need for the device to search for, and obtain, the relevant 3D reference model(s). Thus, for example, a 3D reference model may be staged at a device before the 3D reference model is needed, so that comparisons with the 3D reference model may be performed immediately after a 3D model is generated by the device.

As a final example of features and aspects of an embodiment, a method according to one embodiment may comprise two operational modes, namely, a coarse mode with low resolution rendering, and fine mode with relatively higher resolution rendering than the coarse mode. In an embodiment, the coarse mode could be the primary, or default, mode to enable a relatively faster scan, that is, 2D image capture, than would be possible in the fine mode. Upon detection of an actual, or suspected, anomaly, which may be determined by 3D model comparison for example, the mode may automatically switch from coarse mode to fine mode to reveal more details about the anomaly and related aspects of the target. The operational modes of an embodiment may also comprise, or be integrated with, other techniques such as, for example, IR heatmap modeling techniques, to provide additional functionalities, such as determining a heat signature, and heat distribution, such as may be indicated by thermoclines, of a target.

### C. Detailed Description

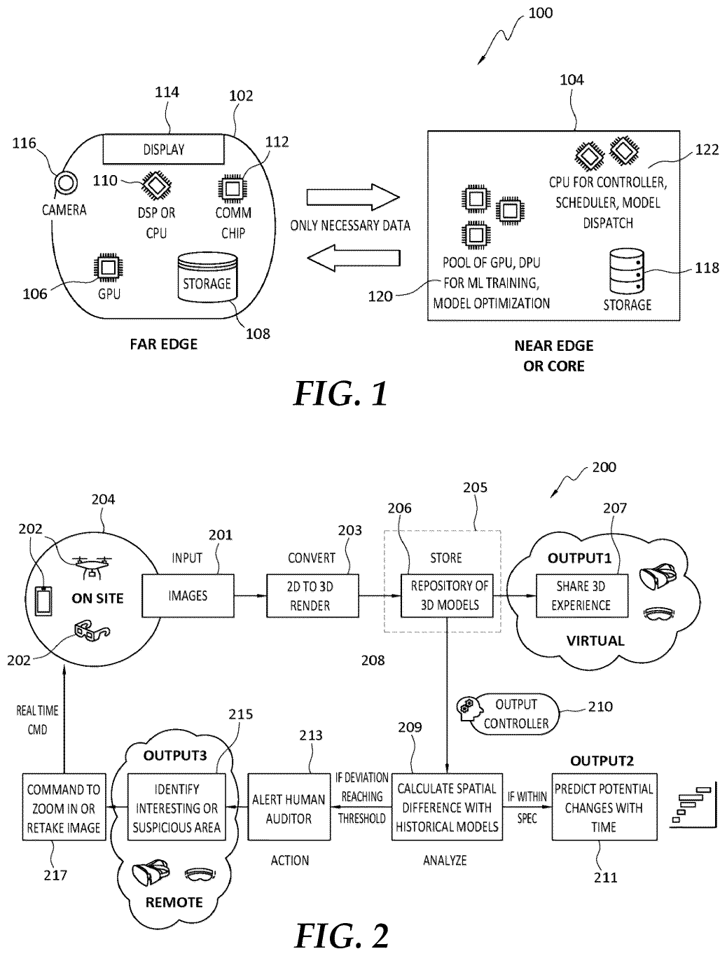

With reference now to FIG. 1, an example architecture 100 according to an embodiment is disclosed. In the example of FIG. 1, one or more small form factor image conversion devices (SFFICD) 102 may operate in a far edge computing environment, and may be configured and operable to perform real time 2D to 3D rendering, and also configured and operable to send/receive data to/from a central system 104 at near edge or core to perform large database, AI/DL training and various control functions as described elsewhere herein.

In one embodiment, the SFFICD 102 may comprise only minimal hardware components, such as a GPU 106 (graphics processing unit) for real time rendering—for example, the 3rd gen RTX chip can deliver real time neural rendering with a single GPU. A portable GPU may also be used to perform rendering at a remote location. In an embodiment, the SFFICD 102 may further comprise a memory card 108 for data storage, a DSP 110 (digital signal processor) or low power CPU 110 (central processing unit) for output controller processing and 3D model comparison, a wireless communication chipset 112 to support WiFi, cellular, satellite, or other wireless, connectivity. The SFFICD 102 may comprise various other components such as, but not limited to, a display 114, an acoustic alarm, and a camera 116.

Among other things, an embodiment of the SFFICD 102 may be configured and operable to generate or render, in real time, a 3D digital model from one or more 2D images, which may be digital. As well, the SFFICD 102 may be configured and operable to obtain 2D images with an onboard camera, and/or to obtain 2D images from an external source.

The SFFICD 102 may perform rendering of a 3D image, from one or more 2D images, in a variety of different ways. For example, an embodiment of the invention may employ Neural Radiation Field (NeRF), and may, in one example, be able to achieve real time view rendering at a speed of 5 fps (frames per second), with a digital resolution of up to 1575×861×1290 while maintaining a file size, in this example, of only 66 MB. Note that the resolution may be defined, for example, by a user, and both the FPS and file size will change with changes in the resolution. If accurate positioning of the camera is performed, more accurate and faster 3D reconstruction can be achieved. Some experimental results obtained by one embodiment are disclosed and discussed elsewhere herein. Using advanced deep learning techniques, for example, and embodiment may extend the 2D to 3D rendering to achieve various computer vision tasks, as well as 3D modeling acceleration.

The NeRF approach may be more accurate, in some instances at least, than the BIM file reconstruction of 3D space which only reflects structural accuracy from a design point of view, rather than reflecting real world condition such as a cracked surface, deformations, and deteriorated parts. Thus, an embodiment of the invention comprises an anomaly detector which is configured and operable to detect anomalies, such as cracks or deformed component parts of the buildings, to focus on the fine tuning on the region of interests. Note that an ‘anomaly’ as used herein is not limited merely to problematic conditions, but more broadly, embraces, among other things, a deviation from a normal, expected, or prior, condition. Thus, one embodiment of the invention may comprise a module for generating RGB based heat synthesis images based on environmental factors such as ambient temperature, and materials deployed, and then those heat synthesis images may be converted to 3D heatmaps to help identify areas at risk for fire, chemical reactions, and other problems.

With continued reference to FIG. 1, a central system 104 according to one embodiment may reside at a local office, or near edge location, or a datacenter/cloud where volume storage 118 may be available for hosting necessary historical data for comparison or compliance. The host site for the central system 104 may also comprise a pool 120 of GPUs and/or DPU (data processing unit) that is available for processes such as AI/ML/DL (deep learning) training, 3D model process optimization to reduce rendering and comparison time and compute power at far edge, root cause analysis and progress prediction. In an embodiment, the central system 104 may comprise a multi-core CPU 122 for dataflow control, task scheduler operations, relevant model dispatch operations, and decision making operations, such as operations based on policy and protocol. An embodiment may be configured to minimize, to various extents, the communication of data between the SFFICD 102 and the central system 104, in order to reduce network bandwidth burden, and latency, and to save energy at the SFFICD 102. Thus, an embodiment may be configured and operable to reduce the amount of data transferred between the SFFICD 102 and the central system 104.

With reference next to FIG. 2, details are provided concerning an example method 200, which may comprise various data flow operations, according to one embodiment. In the example of FIG. 2, various entities at various locations may be involved in one or more aspects of a data flow. Thus, a SFFICD 202 may operate at a remote site, or other edge location 204, to capture, or otherwise access, 2D images. As detailed below, these 2D images, however obtained, may be used to generate various outputs.

Initially, and as noted above, the SFFICD 202 may obtain 201 one or more 2D images, which may then be converted, by the SFFICD 202, in real time 203, to a 3D model of the target of the 2D images. Note that as used herein, a ‘target’ refers to a physical entity, man-made or otherwise, of which one or more 2D images are captured. The 3D model may then be stored 205, such as in a repository 206 of 3D models hosted by a central system 208. In an example consumer use case, the 3D model may be shared 207 with one or more users to enable the users, using VR (virtual reality) goggles and/or comparable equipment, to enjoy a virtual 3D experience, such as an experience of bungee jumping, or flying with a wingsuit, for example. Thus, this shared virtual experience is one example of an output that may be generated using the 3D model. The type of output to be produced, and the data flow for a particular output, may be controlled by an output controller 210 that is configured and operable to communicate with a central system and one or more SFFICDs 202. In an embodiment, the output controller 210 may be hosted by the central system 208, although that is not necessarily required.

In an embodiment, the method 200 may comprise comparing 209 one or more 3D models to each other to enable a calculation of, for example, one or more spatial, and/or other, physical differences between the subjects represented in the 3D models. Differences between the 3D models may be within spec, or acceptable limits, or not. In either case, the differences may be reported. The differences between the 3D models may be used to identify trends in various features of the target such as, for example, an increasing size of a crack in a steel beam. As an example of an output of an embodiment of the invention, such trends may be used to output a prediction 211 of potential changes in the feature over time.

If it is determined at 209 that a difference/delta between 3D models is nearing, has not reached, a defined threshold, an alert may be sent 213 to a human operator and/or other recipient, such as a computing system. Likewise, an alert may be sent if it is determined that the threshold has been exceeded. The alert may indicate, for example, the speed with which the difference is changing, whether the change in the difference has accelerated or not, the nature of the difference, the location of the difference, an extent to which a threshold has been exceeded, and one or more possible remedial actions that may be implemented to slow, stop, or reverse, the change in the difference. By way of illustration, a remedial action may be to weld a crack in a steel beam, while another remedial action may be to replace the steel beam. The remedial actions may, in one embodiment, be ranked in terms of variable such as, but not limited to, time to implement, cost to implement, and expected effective life of the target after the remedial action has been implemented. Where a threshold has been exceeded, the alert may indicate that that an affected structure, such as a bridge for example, should be immediately shut down until repairs can be made.

An alert may be analyzed by a human and/or by a computing system, to identify 215 a region of concern or interest (ROI). The identification 215 of the area of concern or interest is another example of an output that may generated by an embodiment of the invention. In an embodiment, the operations of the method 200 leading up to the identification 215 may be performed in real time so as to enable a user or operator to control, possibly remotely, the SFFICD 202 so that the SFFICD 202 can perform real time actions 217 such as zooming in on an area of interest, retaking a 2D image, and/or other actions. Thus, for example, an alert may indicate that a crack in a beam is growing in size and may not only indicate possible remedial actions, but may also indicate in real time to a human or other entity that additional 2D images may need to be gathered. Thus, alerts may serve as a basis for the performance of near term, and/or long term, actions relating to one or more 3D model differences.

It is noted that as costs for GPUs go down, and power consumption decreases, one or more embodiments may target a wide range of enterprise use cases for processes such as remote inspection and audit, to bring the convenience and efficiency to the daily jobs of many engineers. As another example, an embodiment may equip millions of content creators to bridge the physical and virtual world for better immersive experience.

Below are provided two aspects of experimental results to analyze the efficiency and visual quality of using 2D-to-3D methods: efficiency and visual reconstruction. In these experiments, NeRF was used as the baseline.

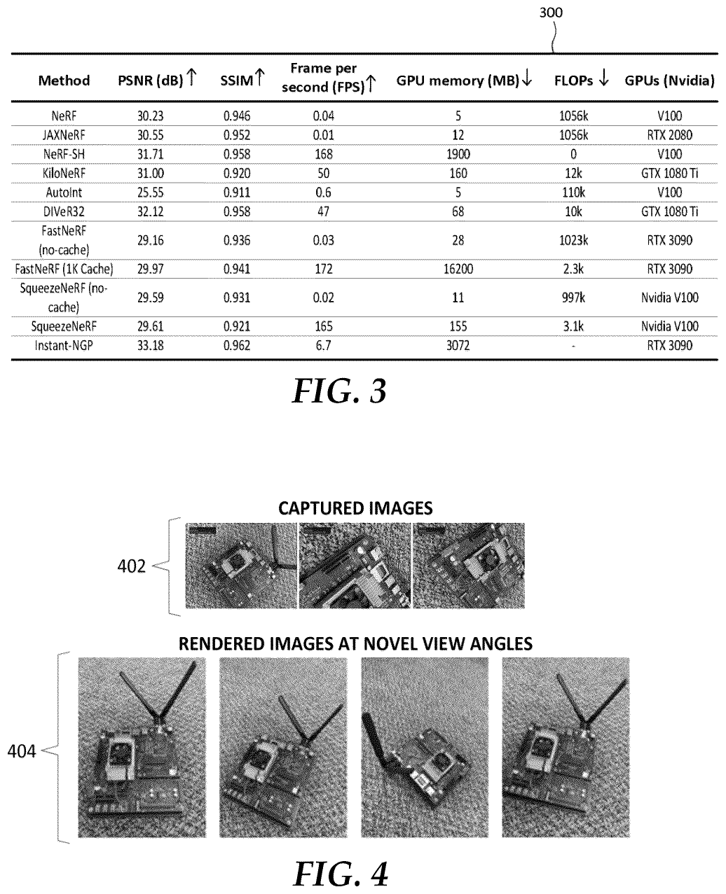

With reference now to FIG. 3, to measure the efficiency of NeRF, a benchmark may be provided of different NeRF methods on 800×800 images in a synthetic 360 dataset. The results are shown in the Table 300. As a practical matter, humans require an application with frame per second (FPS) over 20. It can be seen in the table 300 that many NeRF variations, such as NeRF-SH, KiloNeRF, DIVeR32, FastNeRF, and SqueezeNeRF, can achieve very high FPS which indicate their real time computation ability. Given the fact that these approaches can render images up to 800×800 resolution, an embodiment may adaptively reduce the resolution to further speed up the computation, or alternatively may sacrifice speed for higher resolution. Thus, a tradeoff may be made between resolution and speed.

With reference now to FIG. 4, a cellphone was used to capture 30 images 402 of a circuit board. Then Instant-NGP was used to render the images 404 to reconstruct the 3D model. It can be seen in the images 404 that 2D-to-3D rendering is achievable once high-quality 2D images 402 are provided. From FIG. 4, it can be seen that given captured images 402, an embodiment may construct the 3D model of the circuit and render the novel view angles as shown at 404. Here, it can be seen that the details of circuit board are well captured, and may enable users to check the details of the electronic components in the 3D model. This approach may be applied to reconstruct other objects for users to explore different angles of views.

As noted earlier herein, embodiments of the invention may be employed in a variety of different use cases which may include, but are not limited to, enterprise use cases, and consumer use cases. Examples of each of these are set forth below.

Example enterprise use cases include, but are not limited to, remote inspection, auditing, quality control, and prediction operations. Industries and applications for these use cases may include industries involving physical infrastructure, such as construction, chemical plant, manufacture, oil, and mining. Some example physical infrastructures may include offshore and onshore oil rigs, tunnels, mines and other underground cites, bridges, railroad tracks, buildings, radio towers, cell towers, and electrical power transmission towers. More generally, any physical structure(s), whether man-made or otherwise, that may require or benefit from periodic inspects and audits, such as may be performed by inspectors on-site, or remotely with a UAV for example, may be a target for an embodiment of the invention.

For example, an embodiment may be used to evaluate structures such as bridges, railroad tracks, and pipe connections in chemical plants. An embodiment may enable 3D remote inspection to quickly examine targets at scale. Anyone at the site may use an embodiment of the invention to perform inspection, and would not necessarily be required to be a highly skilled auditor. Further, unmanned vehicles such as drones may be employed for dangerous and/or inaccessible locations, or locations that are cost-prohibitive to access. If all inspect results are in a ‘green’ status, approval for the structure that was inspected may be issued onsite, while captured image/video and a rendered 3D model may be uploaded to a central repository when a wired connection is available for a device such as an SFFICD to plug in. If an area of concern, such as an area with a ‘yellow’ or ‘red’ status, is identified through real time rendering and comparison, such as surface crack propagation, or chemical pipe leaking, an alert may be issued onsite to trigger additional actions such as requesting a remote auditor for expert review. A remote auditor may send instructions in seconds to direct a drone or on-site person to zoom in or view in a different angle to confirm the point(s) of interest. Meanwhile, an embodiment may additionally, or alternatively, alert an authority for emergency preparation according to a predefined policy or protocol. A wireless communication through WiFi, cellular, or satellite, may be particularly useful in enabling rapid communication between the site and other locations.

Example consumer use cases include, but are not limited to, remote immersive experience sharing. In particular, when a person is traveling to different places, the portable device can render the captured 2D images into 3D model in real time so as to enable the person to share a 3D rendering of his or her environment with family, friends or social network. Further, a viewer with VR goggle would have an immersive experience as if traveling with the experiencer. An embodiment may be employed by, for example, a professional photographer, stargazer, mountain climber, scuba diver, bungee jumper, to create their immersive studio to deliver a real time 3D broadcast to one or more customers or clients. A model compressing feature may be added to the image converter to reduce the network bandwidth requirement for live streaming. The device can be used either in real time or non-real time as many people have photos that they may wish to convert to 3D for immersive experience sharing.

Attention is directed now to various real world circumstances in which an embodiment of the invention may have proved to be useful.

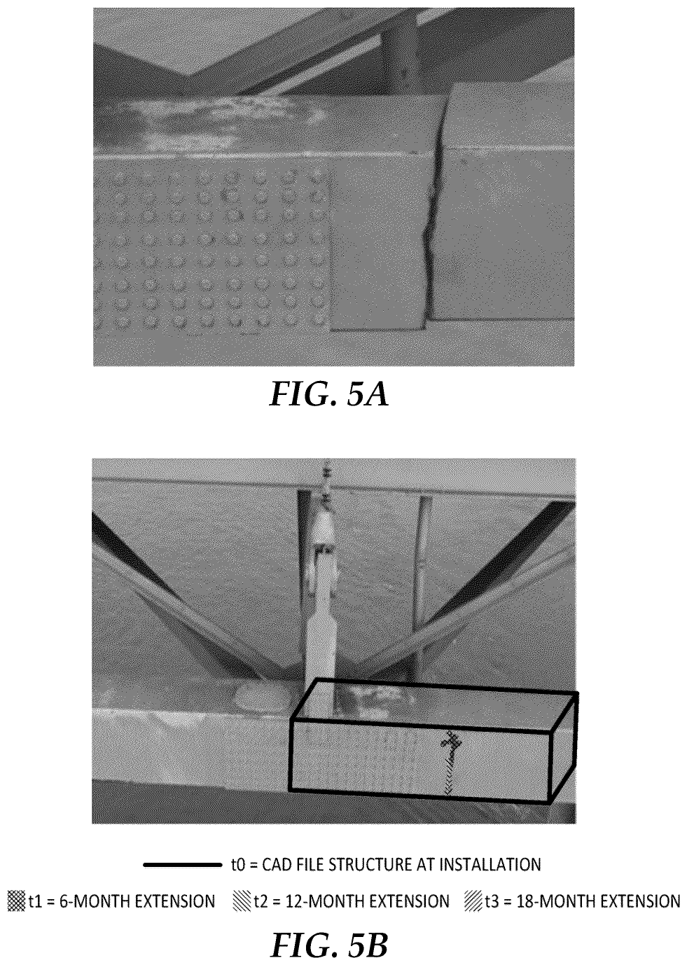

With attention next to FIGS. 5A and 5B, an example of one possible use case for an embodiment of the invention concerns a Mississippi River bridge beam crack (FIG. 5A). The crack in a steel beam forced an emergency three-month shutdown of an Interstate-40 bridge across the Mississippi River in 2021. An embodiment may help to prevent significant service interruptions such as this, thereby possibly saving significant expense, when operations such as those indicated below are performed:
[1] 2D images taken periodically by drone (FIG. 5B) at various times t0, t1, t2, t3;
[2] nearby image converter renders the image to 3D model using technologies such as SfM (Structure from Motion), or NeRF (Neural Radiation Field);
[3] the real time rendered 3D model may be compared with the original design in CAD file or the image of installation—each follow-on inspection may be compared with prior 3D models rendered from periodical inspection results, and stored in a model repository;
[4] the automatic spatial comparison by the image converter provides quick insights on the real condition of the target without the auditor being onsite;
[5] if the comparison result points to an anomaly, or the deviation reaching a pre-set threshold, the system may automatically alert a human auditor and/or computing system to look at 3D models overlay closely to send commands to remotely direct the drone, or other image capturing system/device, to position a camera to take additional images or zoom in to confirm the severity; and
[6] using AI/ML, the changes of the target along a timeline may be used to help identify a root cause of the observed deformation/failure, to predict progression of the deformation/failure if appropriate action is not taken, and to predict when maintenance or other action should be performed to slow, stop, or reverse, the observed condition.

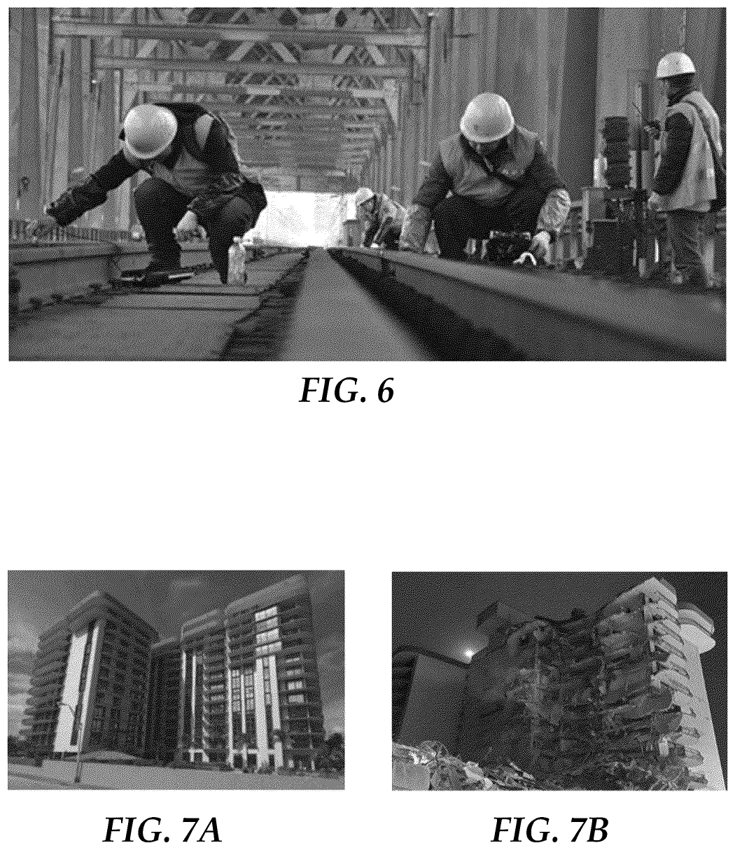

With reference next to FIG. 6, it is noted that a recent heatwave in the UK created a number of emergencies with respect to commuter trains. Particularly, because the steel of the rail track was stress tested at 31° C., while the heatwave caused the local temperature of some tracks to rise as high as 62° C., the track became warped in some locations.

In an embodiment, a group of drones, rather than human inspectors, could survey the track and send photos through wireless connection, while a human in a nearby vehicle with as SFFICD could inspect 3D rendered models in real time and compare those 3D models with a CAD model, or the most recent normal inspection results, to determine the severity of the local deformation, and alert the transportation system authorities as to remedial actions that may be taken, where examples of such remedial action may include, but are not limited to:
[1] spray water to cool off the slightly warped track, thus possibly allowing the trains to continue to operation, although possibly at lower speeds—and announce commute delays to the public; and/or
[2] stop the trains in areas where the track is warped to the point of being unable to be safely used, and announce the cancellation of affected trains/routes—also, advise the public as to alternative transportation options such as bus, rideshare, or taxi, for example.

In these example circumstances, an embodiment of the invention may provide relatively fast 2D image acquisition, and initial 3D rendering in low resolution, to deliver anomaly detection in as short a time as a few seconds. This may enable engineers and other personnel to use high resolution rendering to focus only on affected areas, and then quickly identify corrective action to be taken. Such an approach may reduce the likelihood of an accident, while also improving the user experience. Then, when the human inspector returns to a near edge site, such as an office for example, the 3D files from the SFFICD may be uploaded to a central repository and may be used to update the 3D model for the target. The updated 3D model may then be distributed to all SFFICD for use in a subsequent inspection operation.

With reference next to FIGS. 7A and 7B, it is noted that, in June 2021, Champlain Towers South, a 12-story beachfront condominium in Miami, FL collapsed due, it is believed, to a long-term degradation of reinforced concrete structural support, and 99 deaths were attributed to the collapse. FIG. 7A is a picture of the building prior to collapse, in 2015, and FIG. 7B is a picture of the building after it collapsed in 2021. These circumstances suggest another possible use case for an embodiment of the invention.

Particularly, an SFFICD may be used by an inspector to create a 3D model of current conditions, based on recent 2D images of the target, and to compare the new 3D model with previously rendered 3D models of various structures, such as the basement, parking garage, and pool deck. Delta analytics, comprising differences between the new, and previously created, 3D models may then be used by AI/ML techniques, for example, to identify areas classified as ‘green,’ ‘yellow,’ or ‘red,’ as well as to make predictions as to when, for example, a structure might be expected to fail. All of these operations may be performed in real time as an inspector is performing an inspection of the structures. The analytics and predictions may be used to identify remedial actions, such as steel/concrete replacement or reinforcement that should be taken before any significant problems occur.

It is noted with respect to the disclosed methods, including the example method of FIG. 2, that any operation(s) of any of these methods, may be performed in response to, as a result of, and/or, based upon, the performance of any preceding operation(s). Correspondingly, performance of one or more operations, for example, may be a predicate or trigger to subsequent performance of one or more additional operations. Thus, for example, the various operations that may make up a method may be linked together or otherwise associated with each other by way of relations such as the examples just noted. Finally, and while it is not required, the individual operations that make up the various example methods disclosed herein are, in some embodiments, performed in the specific sequence recited in those examples. In other embodiments, the individual operations that make up a disclosed method may be performed in a sequence other than the specific sequence recited.

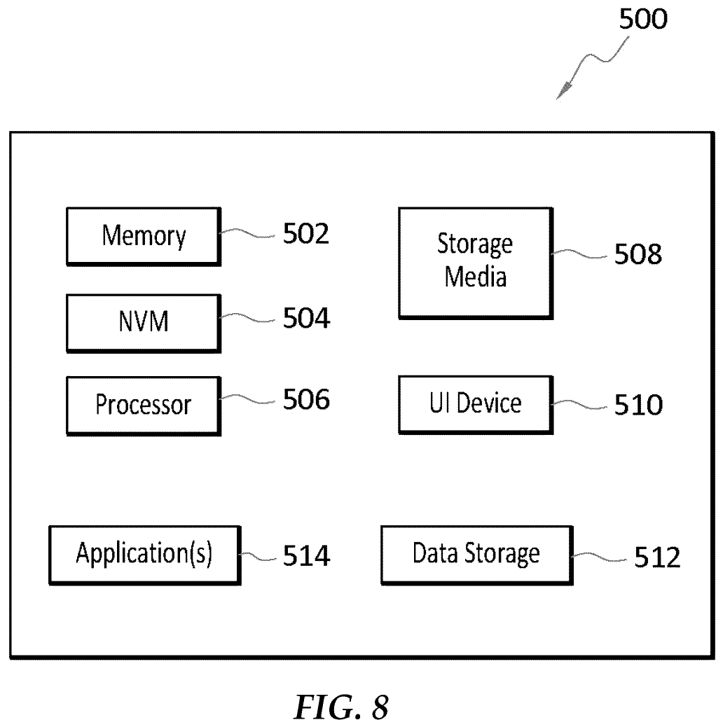

With reference briefly now to FIG. 8, any one or more of the entities disclosed, or implied, by FIGS. 1-7, and/or elsewhere herein, may take the form of, or include, or be implemented on, or hosted by, a physical computing device, one example of which is denoted at 500. As well, where any of the aforementioned elements comprise or consist of a virtual machine (VM), that VM may constitute a virtualization of any combination of the physical components disclosed in FIG. 8.

In the example of FIG. 8, the physical computing device 500 includes a memory 502 which may include one, some, or all, of random access memory (RAM), non-volatile memory (NVM) 504 such as NVRAM for example, read-only memory (ROM), and persistent memory, one or more hardware processors 506, non-transitory storage media 508, UI device 510, and data storage 512. One or more of the memory components 502 of the physical computing device 500 may take the form of solid state device (SSD) storage. As well, one or more applications 514 may be provided that comprise instructions executable by one or more hardware processors 506 to perform any of the operations, or portions thereof, disclosed herein.

Such executable instructions may take various forms including, for example, instructions executable to perform any method or portion thereof disclosed herein, and/or executable by/at any of a storage site, whether on-premises at an enterprise, or a cloud computing site, client, datacenter, data protection site including a cloud storage site, or backup server, to perform any of the functions disclosed herein. As well, such instructions may be executable to perform any of the other operations and methods, and any portions thereof, disclosed herein.

The present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

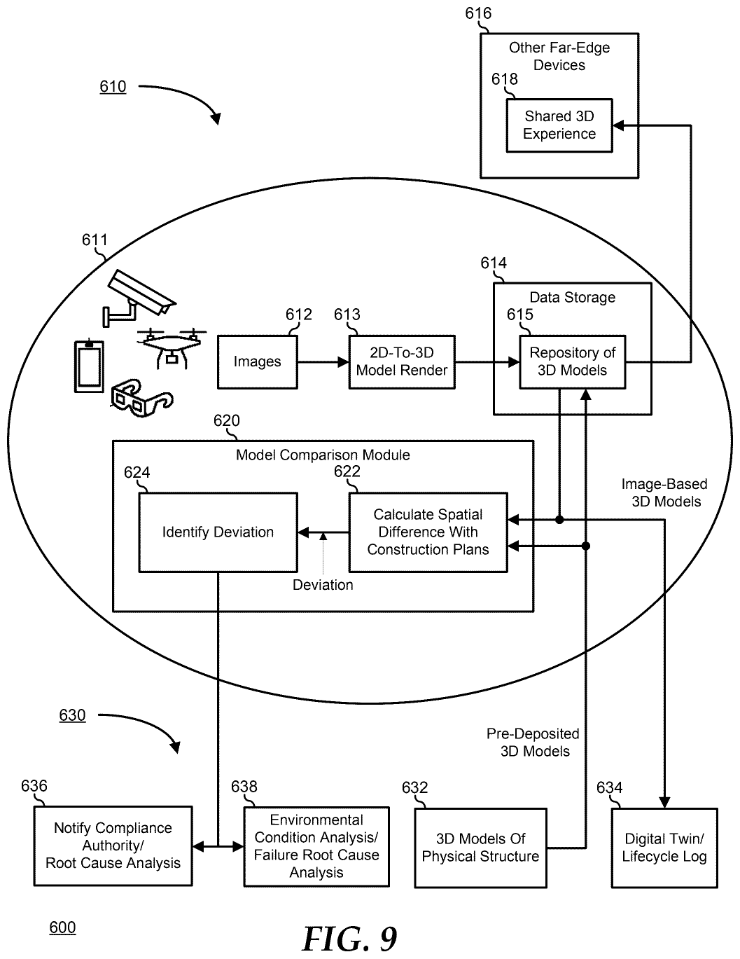

With reference now to FIG. 9, a structure inspection system 600 is illustrated that provides various data flow operations which may be similar to the method described with respect to FIG. 2, above. Structure inspection system 600 includes far edge components 610 and near edge/back end components 630. For the purposes of the current disclosure, the terms “far edge,” “near edge,” and “back end,” may be understood to describe the proximity of the included components with respect to the other components. In this regard, “far edge” may be understood to describe components in a computing infrastructure that are located farthest from the computing resources of a cloud network or datacenter. Further, “near edge” may be understood to describe components in the computing infrastructure that are located between the far edge components and the cloud or datacenter. Finally, “back end” may be understood to describe the cloud network or datacenter.

Generally, the deployment of computing resources and functions as described herein may be provided based upon factors related to the overall computing efficiency of the infrastructure. For example, functions that require low latency, real time, and/or low compute resource utilization may reasonably be located in far edge 610, functions that require medium latency, near real time, and/or medium compute resource utilization may be located in a near edge portion of near edge/back end 630, and functions that can withstand long latencies, can be processed in discretionary timeframes, and/or that require high compute resource utilization may be located in back end portion of the near edge/back end. It may be further understood that the functions and features as described with respect to structure inspection system 600, and particularly the locations of the components of far edge 610 and near edge/back end 630, are exemplary, and the functions, features, and locations of the components may be provided in any location, as needed or desired. All of the teachings as provided above with respect to FIGS. 1-8, and the embodiments described therein, may be incorporated into the embodiment of structure inspection system 600 as described below.

Far edge 610 includes one or more SFFICD 611, and one or more additional far edge device 616. SFFICD 611 may be similar to SFFICD 102 and SFFICD 202, as described above. As such, SFFICD 611 is configured to receive 2D images 612 and to render in real time a 3D digital model from the 2D images by a 2D-to-3D renderer 613. As such, SFFICD 611 may be configured to obtain 2D images 612 from an onboard camera, to obtain 2D images from an external source, or from both an onboard camera and an external source, as needed or desired. An example of SFFICD 611 may include a still or video camera in a mobile device, such as a smartphone, a drone, a pair of AR goggles, or the like. Another example of SFFICD 611 may further include a still or video camera in a fixed device, such as a closed-circuit television (CCT) device, a surveillance camera, or the like. The rendering of 2D image 612 into a real time 3D digital model by renderer 613 may be provided in accordance with any of the embodiments as described above, as needed or desired. In particular, it will be understood that a plurality of views of an object may be useful in rendering a 3D digital model at the far edge of the network infrastructure, as described above.

SFFICD 611 further includes a data storage device 614 similar to the storage 205 as described above. Storage device 614 includes an image repository 615 similar to repository 206 as described above. In particular, image repository 615 may store one or more simplified 3D models of a particular man-made structure or natural feature to provide a template for the rendering of real time 3D model by renderer 613 from 2D image 612, as described above, and as further described below. In particular, image repository 615 may include one or more baseline 3D models of a physical structure of interest, such as a building, a man-made feature such as a park or a statue, a natural feature, a man-made modification to a natural feature, a load bearing structure, or any other object whose features are intended to remain relatively static over time, or whose features are expected to shift slowly over time. The one or more baseline 3D models may be utilized as a basis for the rendering 613 of images 612 from the inspection site, as described further below. In this way, the rendering 613 of the images 612 from the inspection site can be provided by SFFICD 611 more quickly and with less processing than would otherwise be needed to render 2D images into real time 3D models. Far edge device 616 operates to host a shared 3D experience 618 with the user of the far edge device as described further below.

Contemporary inspection activities face various pressures that increase the demand for specialized inspections and methods. Regular inspections play a vital role in mitigating risks for insurers and ensuring the longevity and integrity of structures. It has been understood by the inventors of the current disclosure that the current approach to inspections in contemporary inspection site activities may include various challenges, such as: an inadequate number of qualified inspectors, or inspectors who lack knowledge of the latest procedures and regulations; human error or laziness; increasingly frequent inspections; and potential corruption among human inspectors. The volume and frequency of inspections may further burden contemporary activities in order to ensure accurate Digital Twin models of the inspection site.

Utilizing the 2D to 3D rendering capabilities of SFFICD 611, structure inspection system 600 operates to monitor, manage, and maintain various types of physical structures. In particular, structure inspection system 600 operates to provide initial real time 3D models of the physical structures and to identify deviations from the initial real time 3D models, enabling immediate notification to management and maintenance authorities, accompanied by detailed information regarding the deviations, permitting the prompt implementation of corrective measures as needed or desired. In a particular embodiment, SFFICD 611 operates to render the 3D models based upon images 612 to establish baseline 3D models. In another embodiment, SFFICD 611 operates to render the 3D models based upon images 612, and the 3D models of the structures of interest that were stored in repository 615, as described above. Here, it will be noted that rendering 3D models of the structures of interest based only upon images 612 may take a longer duration of time, and utilize a greater portion of the processing resources of SFFICD 611 than may be the case when the 3D models are rendered upon the stored 3D models in addition to the images. Structure inspection system 600 further operates to generate a comprehensive, real time log 634 of the history of the physical structures, which may prove invaluable for insurance purposes and catastrophe investigations and creating the real-world Digital Twin instance of the inspection site.

In this regard, near edge/back end 630 operates to provide baseline 3D models 632 of an inspection site based upon the project plans and other relevant information, as needed or desired. Baseline 3D models 632 may be provided based upon the plans or drawings, models, or the like, of the physical structures in the inspection site. As such, baseline 3D models 632 may include various computer aided design (CAD)/computer aided manufacturing (CAM) renders, or the like. Baseline 3D models 632 are uploaded to repository 615 for use in rendering the real time 3D models, as described above, and for identifying deviations from the initial real time 3D models, as described below.

SFFICD 611 operates to periodically image the inspection site and to render the 2D images into the real time 3D models of the physical structures of the inspection site, as described above. In particular, SFFICD 611 can be directed to take images 612 for the scheduled inspections, and renderer 613 can render the 2D images into the real time 3D models of the physical structures at the time of the scheduled inspection. The real time 3D models are stored in data storage 614, and can be viewed in real time, or recovered at a later time by far edge device 616 as described above.

Moreover, SFFICD 611 further operates to compare real time 3D models 613 with baseline 3D models 632. More particularly, SFFICD 611 includes a model comparison module 620 that includes an evaluation module 622 that operates to perform the comparisons and to evaluate if the real time 3D models have deviated from the baseline 3D models, and if so, by how much. In a particular embodiment, evaluation module 622 utilizes various AI/ML/DL functions to perform the evaluations. When evaluation module 622 detects a deviation, a violation module 624 operates to identify the deviation as described above, and to determine if the deviation exceeds a projected variation threshold. If so, evaluation module 622 provides an alert to a compliance authority 636, as needed or desired. Here, it will be understood that such an alert may be provided in the form of shared 3D experience 618, as described above. In particular, the alert may be provided as a green/yellow/red indication.

Model comparison module 620 further operates to characterize the deviation. In particular, model comparison module 620 operates to highlight the deviation, and to provide qualitative and quantitative analysis of the deviation. For example, model comparison module 620 can operate to evaluate a quantity for the deviation, such as a crack length, a length of movement, a volume change, or the like, a quality of the deviation, such as a smoothness, a color, or the like, or other aspects of the deviation, as needed or desired. Moreover, model comparison module 620 can provide characterization information related to the environmental conditions, such as temperature, atmospheric pressure, humidity, or the like, at the time of the deviation. Such characterization information may further include timestamp information or the like.

In addition to the alert being provided to compliance authority 636, the alert, along with the characterization of the deviation is provided to an analysis module 638 in near edge/back end 630. Analysis module 638 operates to retrieve the alert and characterization information from model comparison module 620. Such characterization information may be utilized by analysis module 638 to evaluate the environmental conditions and the like to provide a failure projection or root cause analysis, as needed or desired. Analysis module 638 can further operate to provide a recommendation for remedial action to return the physical structure at the inspection site into compliance with the baseline 3D models. Here, the recommendation may be provided to one or more experienced inspector. In this case, note that the involvement of the inspector is reduced from the normal need to visually and personally perform the inspection, to consult and consider the plans, codes, and regulations, and to make the determination that the real time 3D model status has deviated from the baseline 3D model status. In another case, the recommendation for the remedial action may be provided by an AI/ML expert system that emulates the decision making ability of the human inspector, as needed or desired.

Structure inspection system 600 thus provides an automated, closed-loop process to dispatch, inspect, analyze, root cause, and preventively maintain the inspected structures with minimized compute deployment in far edge 610. The real time on-site 3D rendering provides real-time analysis, thereby allowing a single auditor to manage a large number of structures remotely, quickly, and simultaneously, with much less travel cost. Repository 618 serves as a valuable digital asset with historical records to construct a Digital Twin of the structures. The Digital Twin feeds studies of materials, architectures, environmental conditions, and the like, and verifies multiple options before physical deployments to improve structure life cycle and future designs.

Although only a few exemplary embodiments have been described in detail herein, those skilled in the art will readily appreciate that many modifications are possible in the exemplary embodiments without materially departing from the novel teachings and advantages of the embodiments of the present disclosure. Accordingly, all such modifications are intended to be included within the scope of the embodiments of the present disclosure as defined in the following claims. In the claims, means-plus-function clauses are intended to cover the structures described herein as performing the recited function and not only structural equivalents, but also equivalent structures.

The above-disclosed subject matter is to be considered illustrative, and not restrictive, and the appended claims are intended to cover any and all such modifications, enhancements, and other embodiments that fall within the scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed:

1. A structure inspection system, comprising:
an image conversion device configured to receive a plurality of first images of a physical structure, and to render a first real time three-dimensional (3D) model of the physical structure based on the first images, wherein the image conversion device is located in a far edge of the structure inspection system that is proximate to the physical structure; and
a near edge processor configured to provide a baseline 3D model of the physical structure to the image conversion device, wherein the near edge processor is located in a near edge of the structure inspection system that is remote from the physical structure;
wherein the image conversion device is further configured to compare the first real time 3D model with the baseline 3D model, and to provide an indication when the first real time 3D model deviates from the baseline 3D model.

2. The structure inspection system of claim 1, wherein the image conversion device includes a repository to store the first real time 3D model and the baseline 3D model.

3. The structure inspection system of claim 2, wherein the image conversion device utilizes the baseline 3D model from the repository in rendering the first real time 3D model.

4. The structure inspection system of claim 1, wherein the near edge processor is further configured to provide a lifecycle log of the physical structure.

5. The structure inspection system of claim 4, wherein the lifecycle log includes the first real time 3D model and the baseline 3D model.

6. The structure inspection system of claim 5, wherein the lifecycle log further includes a second real time 3D model of the physical structure.

7. The structure inspection system of claim 6, wherein the second real time 3D model is rendered from a plurality of second images of the physical structure by the image conversion device.

8. The structure inspection system of claim 1, wherein in the determination of whether the first real time 3D model deviates from the baseline 3D model, the image conversion device is further configured to determine that the first real time 3D model violates a regulation governing the physical structure.

9. The structure inspection system of claim 8, wherein the indication identifies the regulation.

10. The structure inspection system of claim 1, wherein the image conversion device includes an image capture device configured to generate the image.

11. A method, comprising:
providing, in a structure inspection system, an image conversion device, wherein the image conversion device is located in a far edge of the structure inspection system that is proximate to a physical structure;
receiving, by the image conversion device, a first images of the physical structure;
rendering, by the image conversion device, a first real time three-dimensional (3D) model of the physical structure based on the first images;
providing, in the structure inspection system, a near edge processor, wherein the near edge processor is located in a near edge of the structure inspection system that is remote from the physical structure;
providing, by the near edge processor, a baseline 3D model of the physical structure to the image conversion device;
comparing, by the image conversion, the first real time 3D model of the physical structure with the baseline 3D model; and
providing, by the image conversion device, an indication when the real time 3D model deviates from the baseline 3D model.

12. The method of claim 11, further comprising:
providing, in the image conversion device, a repository to store the first real time 3D model and the baseline 3D model.

13. The method of claim 12, wherein the image conversion device utilizes the baseline 3D model from the repository in rendering the first real time 3D model.

14. The method of claim 1, further comprising:
providing, in the near edge processor, a lifecycle log of the physical structure.

15. The method of claim 14, wherein the lifecycle log includes the first real time 3D model and the baseline 3D model.

16. The method of claim 15, wherein the lifecycle log further includes a second real time 3D model of the physical structure.

17. The method of claim 16, wherein the second real time 3D model is rendered from a plurality of second images of the physical structure by the image conversion device.

18. The method of claim 11, wherein in the determination of whether the first real time 3D model deviates from the baseline 3D model, the method further comprises:
determining that the first real time 3D model violates a regulation governing the physical structure.

19. The method of claim 18, wherein the indication identifies the regulation.

20. A structure inspection system, comprising:
an image conversion device including an image capture device and a repository, the image capture device to generate an image of a physical structure, the image conversion device being configured to render a real time three-dimensional (3D) model of the physical structure based on the image and to store the real time 3D model to the repository, and being located in a far edge of the structure inspection system that is proximate to the physical structure; and
a near edge processor configured to store a baseline 3D model of the physical structure to the repository, the near edge processor being located in a near edge of the structure inspection system that is remote from the physical structure;
wherein the image conversion device is further configured to compare the real time 3D model with the baseline 3D model, and to provide an indication when the real time 3D model deviates from the baseline 3D model.
